(19) United States
(12) Patent Application Publication
(10) Pub. No.: US 2016/0050492 A1
(43) Pub. Date: Feb. 18, 2016

(54) DIRECT-DRIVE DIGITAL AUDIO AMPLIFIER FOR ELECTROSTATIC LOUDSPEAKERS

(71) Applicants: Dezarae HOLMAN, (US); John KOTA, (US); Kyle WILSON, (US); Eric MATAS, (US); Habarakada Liyanachchi MADANAYAKE, (US); Malik E. ELBULUK, (US)

(72) Inventors: Dezarae Holman, Cleveland, OH (US); John Kota, Chandler, AZ (US); Kyle Wilson, Brunswick, OH (US); Eric Matas, Newton Falls, OH (US); Habarakada Liyanachchi Madanayake, Akron, OH (US); Malik E. Elbuluk, Richfield, OH (US)

(73) Assignee: The University of Akron, Akron, OH (US)

(21) Appl. No.: 14/770,564

(22) PCT Filed: Feb. 26, 2014
(86) PCT No.: PCT/US14/18645

§ 371 Date: Aug. 26, 2015

Related U.S. Application Data
(60) Provisional application No. 61/769,464, filed on Feb. 26, 2013.

(51) Int. Cl. H04R 3/06; H04R 19/02; H03F 3/181

(52) U.S. Cl. CPC H04R 3/06; H03F 3/181; H04R 19/02

(57) ABSTRACT

A direct-drive digital audio amplifier for electrostatic loudspeakers (ESL) includes a pulse-width-modulation (PWM) generator that generates a PWM signal from a digital audio signal received from an audio source. The generated PWM signal is amplified to a high voltage, such as several hundred volts, by a high-voltage switching circuit. The amplified PWM signal is then applied to the stator panels of the electrostatic loudspeaker (ESL), whereupon the amplified PWM signal is low-pass filtered by the electrostatic loudspeaker to generate audible sound waves, which are then high-pass filtered by a listener's ears, so as to audibly reproduce the digital audio signal.

### CROSS-REFERENCE TO RELATED APPLICATIONS

This application claims the benefit of International Application No. PCT/U.S. 2014/018645 filed on Feb. 26, 2014, which claims the benefit of U.S. Provisional Application No. 61/769,464 filed on Feb. 26, 2013, the content each of which is incorporated herein by reference.

### TECHNICAL FIELD

Generally, the present invention relates to digital audio amplifiers. In particular, the present invention relates to digital audio amplifiers for electrostatic loudspeakers (ESL). More particularly, the present invention relates to a direct-drive digital audio amplifier that generates a high-voltage pulse-width-modulated (PWM) signal for directly driving electrostatic loudspeakers.

### BACKGROUND OF THE INVENTION

An electrostatic loudspeaker (ESLs) 10, as shown in FIG. 1, generally utilizes a pair of spaced conductive stator panels 20A-B that allows movement of a conductive diaphragm or membrane 30 disposed therebetween. In particular, the membrane 30 is substantially rectangular in shape and is uniformly tensioned and is typically formed of plastic coated with conductive material, such as graphite, and is spaced from both of the stator panels 20A-B by air gaps 32A-B. The stator panels 20A-B are perforated and include a plurality of apertures 40 to allow air to pass therethrough. Thus, during operation of the electrostatic loudspeaker 10, the membrane 30 is charged, while the stator panels 20A-B receive high-voltage audio signals from an audio amplifier, whereupon a uniform electrostatic field that is proportional to the high-voltage audio signal is created between the stator panels 20A-B. As such, a push-pull force is exerted on the membrane 30, causing it to move back and forth. This movement forms radiated acoustic plane waves in the surrounding air, which allows the amplified audio signal to be reproduced as audible sound waves.

ESLs 10 are desirable because they provide significantly lower levels of total harmonic distortion (THD) in the mid-to-high audio band of about 256 Hz to 22 kHz as compared to most conventional moving coil loudspeakers. The low THD provided by the electrostatic loudspeaker 10 is the result of the linear force-distance relationship that is present in the push-pull stator panels 20A-B, the non-resonant property of rectangular electrostatic membrane 30, and the non-existence of baffle effects due to non-use of an enclosure box by the ESL 10. Because the membrane 30 of the ESL 10 is uniformly driven within a highly linear electric field, the ESL does not generate unwanted distortion and resonance, such as cone break-up distortion and resonances that lead to “honking” and “booming” sounds that are generated by a typical center voice-coil driven loudspeakers. As such, electrostatic loudspeakers (ESLs) 10 provide high quality, pristine audio fidelity due to its non-resonant linear operation, making them desirable in high-end audio applications.

However, electrostatic loudspeakers (ESLs) 10 are difficult to drive by conventional audio amplifiers because ESLs 10 are a highly-capacitive load that increases with frequency. This is in contrast to typical dynamic loudspeakers, which are inductive loads. Thus, when a conventional audio amplifier is used to drive an ESL 10, the capacitive load of the ESL 10 is multiplied by the square of the turns ratio of the step-up audio transformer, causing substantial reactive electrical currents to flow in the audio power amplifier output stage. For example, at about 20 kHz, the real power load (acoustic output) would typically be approximately 8 Ohms, but the reactive parallel impedance due to capacitance can be as low as −j0.5 Ohms, leading to current clipping in most amplifiers. Thus, capacitively loaded loudspeakers, such as electrostatic loudspeakers (ESL) 10, are difficult to drive at higher frequencies. While various advances in conventional amplifier design have been made, which are capable of significant reactive power handling to enable the operation of electrostatic loudspeaker 10, such amplifiers are extremely expensive. Furthermore, another problem with the use of conventional amplifiers in driving ESLs 10 is that the step-up transformer needed to impedance match the electrostatic loudspeaker (ESL) 10 to the conventional low-voltage high-fidelity audio power amplifier is bulky, difficult to design and fabricate, and is expensive.

Therefore, there is a need for a direct-drive digital audio amplifier that directly drives electrostatic loudspeakers (ESL). In addition, there is a need for a direct-drive digital audio amplifier that does not require impedance matching with electrostatic loudspeakers (ESL). Furthermore, there is a need for a direct-drive digital audio amplifier that does not utilize expensive step-up transformers to impedance match an electrostatic loudspeaker (ESL) to the direct-drive audio amplifier. In addition, there is a need for a direct-drive digital audio amplifier for an electrostatic loudspeaker (ESL) that is capable of generating a high-voltage digital output signal by switching high voltages at fast speeds.

Still yet, there is a need for a direct-drive digital audio amplifier for driving electrostatic loudspeakers that is low-cost.

### SUMMARY OF THE INVENTION

In light of the foregoing, it is a first aspect of the present invention to provide a digital audio amplifier for an electrostatic loudspeaker having a pair of fixed stators that are separated by a charged membrane, the digital audio amplifier comprises a pulse-width-modulation (PWM) generator adapted to receive a digital audio signal, said PWM generator formatting said digital audio signal into a digital pulse-width-modulation (PWM) input signal; a complement generator coupled to said PWM generator that is configured to output a PWM complement signal by generating a Boolean complement of said digital PWM input signal; and an amplification circuit having an input coupled to said PWM generator and coupled to said complement generator, such that said amplification circuit digitally amplifies said digital PWM input signal and said PWM complement signal; wherein an output of said amplification circuit is coupled to the stators of the electrostatic loudspeaker such that said amplified digital PWM signal is applied to one stator and said amplified digital PWM complement signal is applied to the other stator.

It is another aspect of the present invention to provide a method of driving an electrostatic loudspeaker having a pair of fixed stators separated by a charged membrane, the digital audio amplifier comprising the steps of receiving a digital audio signal at a pulse-width-modulation (PWM) generator; formatting said digital audio signal as a digital PWM input signal; generating a digital PWM complement signal by calculating the Boolean complement of said PWM input signal at a complement generator; amplifying said digital PWM input signal and said digital PWM complement signal at an amplification circuit; and applying said amplified digital PWM signal to the fixed stators of said electrostatic loudspeaker, whereupon said electrostatic loudspeaker generates audible sound waves therefrom.

### BRIEF DESCRIPTION OF THE DRAWINGS

These and other features and advantages of the present invention will become better understood with regard to the following description, appended claims, and accompanying drawings wherein:

FIG. 1 is a perspective view of a prior art electrostatic loudspeaker (ESL);

FIG. 2 is an elevational view of the prior art electrostatic loudspeaker (ESL);

FIG. 3 is a block diagram of a direct-drive digital audio amplifier for use with electrostatic loudspeakers in accordance with the concepts of the present invention; and

FIG. 4 is a schematic view of the direct-drive digital audio amplifier for use with electrostatic loudspeakers in accordance with the concepts of the present invention.

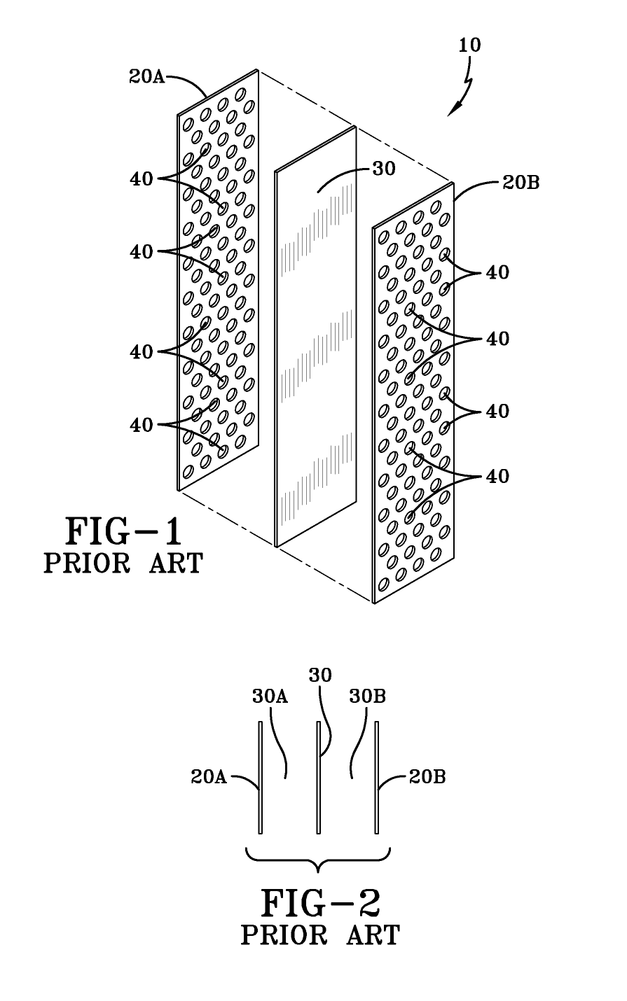

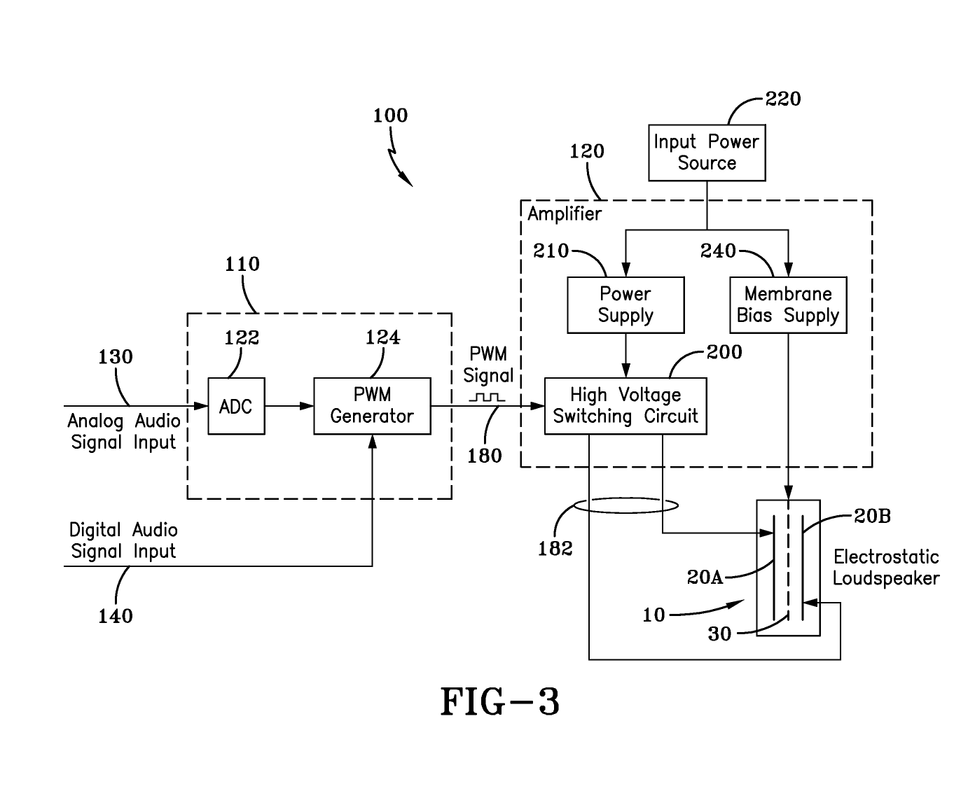

### DETAILED DESCRIPTION OF THE INVENTION

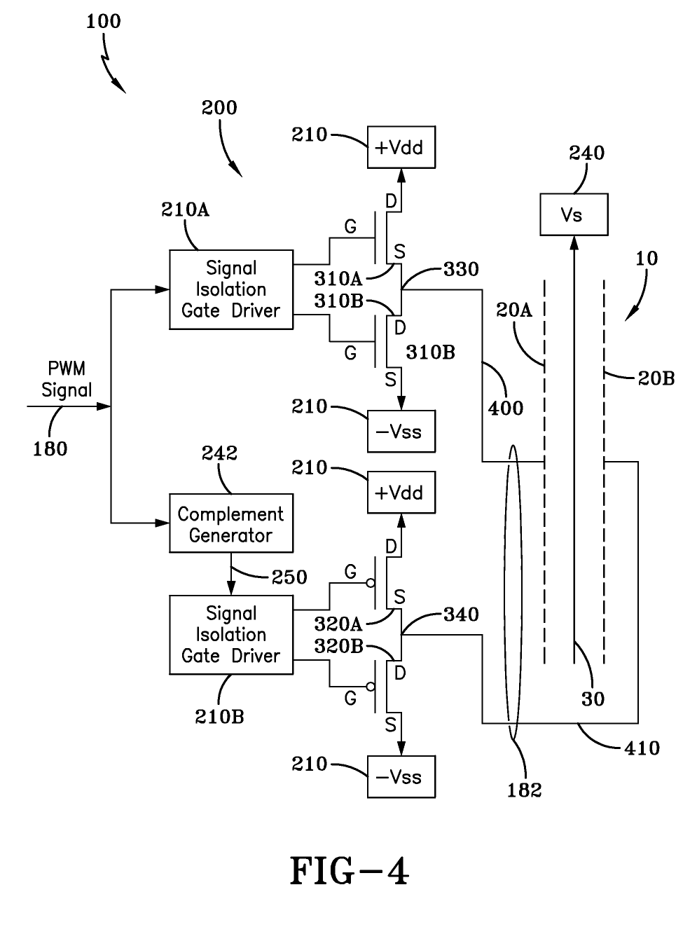

A direct-drive digital audio amplifier for use with the electrostatic loudspeaker (ESL) 10 is generally referred to by numeral 100 as shown in FIG. 3 of the drawings. Specifically, the digital audio amplifier 100 includes a signal processing stage 110 that is coupled to an amplification stage 120. The signal processing stage 110 includes an analog-to-digital converter (ADC) 122 that is coupled to a pulse width modulation (PWM) generator 124. As such, the signal processing stage 110 is configured to receive analog audio signals and/or digital audio signals. In particular, the ADC 122 of the signal processing stage 110 is configured to receive an analog audio signal input 130 from an analog audio source, such as a phonorecord player or analog cassette tape player, whereupon the analog audio signal is converted to a digital bit stream. In addition, the PWM generator 124 of the signal processing stage 110 is configured to receive a digital audio signal input 140 from a digital audio source, such as a compact disc (CD) player, a digital audio tape (DAT) player, as well as any other digital output device, such as a computer or MP3 player for example, that utilizes a CODEC to generate an audio signal represented as a digital bit stream from a stored data file. It should be appreciated, that the digital audio signal 140 may be further processed using known techniques to enable compatibility with the operation of the PWM generator 124.

The PWM generator 124 may be embodied in hardware, software, or a combination of both. As such, the PWM generator 124 is configured to convert or otherwise format the digital audio signal output from the ADC 122 or the digital audio signal that is directly provided by the digital audio source 140 into a digital pulse width modulation (PWM) signal 180. The PWM signal 180 may be generated using any known technique. For example, in one aspect, the PWM generator 124 may generate the PWM signal 180 by comparing an analog wave to a carrier wave, such as a saw-tooth wave. If the analog signal is greater than the saw-tooth amplitude then the output is represented digitally as a 1. Alternatively, if the analog signal is less than the saw-tooth wave then the output is a digital 0.

The PWM signal 180 is delivered to a high-voltage switching circuit 200 provided by the amplification stage 120. In particular the high-voltage switching circuit 200 receives power from a DC (direct current) power supply 210, which generates a high-voltage of several hundred volts or more, from an input power source 220 coupled thereto, such as that provided by a standard electrical wall outlet or the like. As such, the high-voltage switching circuit 200 converts the PWM signal 180 into an amplified PWM signal 182 that is applied to the stators 20A-B of the ESL 10 in a manner to be discussed in detail below. It should be appreciated that in one aspect, the input power source 220 may comprise a 120V AC (alternating current) power source for example; however, any other suitable power source may be used. The input power source 220 is also coupled to a membrane bias power supply 240, which is configured to generate a voltage that is applied to the membrane 30 of the electrostatic loudspeaker (ESL) 10, so that the membrane 30 is charged to a high voltage of several thousand volts, such as approximately 3.5KV, however, other suitable voltages may be used.

With reference to FIG. 4, the high-voltage switching circuit 200 is clearly shown, and includes signal isolation gate driver circuits 210A-B, which may be embodied using hardware, software or a combination of both. In particular, the input of the signal isolation gate driver 210B is coupled to a Boolean complement generator 242, which may also be embodied in hardware, software or a combination of both. The complement generator 242 is configured to take the Boolean complement of the digital PWM input signal 180 to generate a PWM complement signal 250. As such, the PWM signal 180 (i.e. true PWM signal), and the PWM complement signal 250, are coupled to respective signal isolation gate drivers 210A-B. The signal isolation gate drivers 210A-B are configured to isolate the PWM signal 180 and the PWM complement signal 250 input to the amplification stage 120 from the high voltage that is applied by the high-voltage switching circuit 200. For example, the signal isolation gate drivers 210A-B may utilize an opto-coupler circuit to perform this isolation process, as well as any other suitable means. Accordingly, the signal isolation gate drivers 210A and 210B serve to respectively couple the PWM signal 180 and the PWM complement signal 250 to the high-voltage switching circuit 200.

The high-voltage switching or amplification circuit 200 comprises an H-bridge amplification circuit, which includes respective series coupled semiconductor switches 310A-B and series coupled semiconductor switches 320A-B, such as metal oxide semiconductor field effect transistors (MOSFET). In one aspect, the switches 310A-B and 320A-B are configured to have a Vds of about 1500V at about 2.5A. In one aspect, the semiconductor switches 310A-B comprise n-type MOSFETs, while the semiconductor switches 320A-B also comprise n-type MOSFETs. Configuring the H-bridge 200 with all n-type MOSFETS allows the voltages and internal resistances to remain equal, so the H-bridge is balanced. However, it should be appreciated that the semiconductor switches 310A-B and 320A-B may comprise all p-type MOSFETS for example. It should also be appreciated, that the inputs to the gates G of the semiconductor switches 320A and 320B are the Boolean complement of the input to the gates G of the semiconductor switches 310A and 310B. In particular, the signal isolation gate driver 210A is coupled to the gate terminal G of each of the semiconductor switches 310A-B, while the signal isolation gate driver 210B is coupled to the gate terminal G of each of the semiconductor switches 320A-B. Furthermore, the switches 310A-B are coupled so that the source terminal S of the switch 310A is coupled to a positive power source +Vdd provided by power supply 210, while the drain terminal D is coupled at a node 330 to the drain terminal D of the switch 310B. The source terminal S of the switch 310B is coupled to a negative power source −Vss provided by power supply 210.

Similarly, the switches 320A-B are coupled so that the source terminal S of the switch 310A is also coupled to a positive power source +Vdd provided by power supply 210, while the drain terminal D is coupled at a node 340 to the drain terminal D of the switch 320B. The source terminal S of the switch 320B is coupled to a negative power source. In addition, the source terminal S of the switch 320B is coupled to a negative power source −Vss provided by power supply 210. It should be appreciated that the voltage of +Vdd may comprise several hundred volts and −Vss may comprise several hundred volts. For example, +Vdd and −Vss may comprise voltages in the range of about 0V to 1500V, and in one aspect +Vdd may be about 900V and −Vss may be about −900V for example for a differential amplifier output voltage of about +/−1800V. However, it should be appreciated that +Vdd and −Vss may take on any other suitable voltages.

As such, the PWM signal 180 output by the gate driver 210A toggles the semiconductor switches 310A-B and the PWM complement signal 250 output by the gate driver 210B toggles the semiconductor switches 320A-B, such that an amplified digital PWM input signal 400 and amplified digital PWM complement signal 410 are generated at respective nodes 330 and 340. The nodes 330 and 340 are coupled to respective stators 20A and 20B of the electrostatic loudspeaker (ESL) 10. As such, the amplifier 100 achieves class-D digital amplification because the amplified digital audio signals 400,410 driving the stator panels 20A-B of the ESL 10 are in fact digital in nature because they are quantized to one of two possible values +Vdd or −Vss, which correspond to a logic 1 or logic 0. That is, the amplified signals 400,410 output by the nodes 330,340 of the high-voltage switching circuit 200 comprises a differential 1-bit pulse-width-modulation (PWM) waveform that leads to class-D amplification at high voltage. As such, the amplifier 100 generates amplified digital PWM audio signals 400,410 at the operational voltage of a stator panel 20A-B of several thousand volts, thereby removing the need for costly step-up transformers. Such operation is achievable due to the ability of the switching circuit 200 to switch high voltages at fast speeds. For example, the differential output of the amplifier to the ESL 10 is approximately +/−1800V As such, the amplified digital PWM signals 400 and 410 cause a varying electrostatic field to be created at the stators 20A-B of the ESL 10, which cause the membrane 20 to be pushed and pulled, so as to create audible sound waves in the surrounding air. Furthermore, due to the nature of the ESL 10, it performs low-pass filtering of the received digital PWM input signal 400 and the digital PWM complement signal 410, while the auditory frequency response of the human ear leads to recovery of the low-pass audio spectrum from the generated sound wave within the auditory band. That is, due to the configuration of the electrostatic loudspeaker (ESL) 10, it acoustically forms a high-pass filter (HPF) at the listener's ear, such that together with the listener's low-pass response they form a band-pass filter (BPF). Such filtering characteristic of the ESL 10 is utilized by the amplifier 100 to allow the digital PWM signal 400,410 output by the amplifier 100 to be converted into an audible sound wave by the listener.

Therefore, one advantage of the present invention is that a direct-drive digital audio amplifier for electrostatic loudspeakers (ESL) eliminates the use of a step-up audio power transformer. In addition, an advantage of the present invention is that a direct-drive digital audio amplifier for electrostatic loudspeakers (ESL) eliminates the need to impedance match audio transformers with the audio signals. Another advantage of the present invention is that a direct-drive digital audio amplifier for electrostatic loudspeakers (ESL) does not require a digital-to-analog (DAC) conversion to drive the electrostatic loudspeakers. Still another advantage of the present invention is that a direct-drive digital audio amplifier for electrostatic loudspeakers (ESL) generates a digital audio signal that is low-pass filtered by the ESL that together with the auditory response of the human ear leads to the recovery of the low-pass audio spectrum within the auditory frequency band. Still another advantage of the present invention is that a direct-drive digital audio amplifier provides highly efficient amplification with low distortion.

Thus, it can be seen that the objects of the invention have been satisfied by the structure and its method for use presented above. While in accordance with the Patent Statutes, only the best mode and preferred embodiment has been presented and described in detail, it is to be understood that the invention is not limited thereto or thereby. Accordingly, for an appreciation of the true scope and breadth of the invention, reference should be made to the following claims.

What is claimed is:

1. A digital audio amplifier for an electrostatic loudspeaker having a pair of fixed stators separated by a charged membrane, the digital audio amplifier comprising:
a pulse-width-modulation (PWM) generator adapted to receive a digital audio signal, said PWM generator formatting said digital audio signal into a digital pulse-width-modulation (PWM) input signal;
a complement generator coupled to said PWM generator that is configured to output a PWM complement signal by generating a Boolean complement of said digital PWM input signal; and
an amplification circuit having an input coupled to said PWM generator and coupled to said complement generator, such that said amplification circuit digitally amplifies said digital PWM input signal and said PWM complement signal;
wherein an output of said amplification circuit is coupled to the stators of the electrostatic loudspeaker such that said amplified digital PWM signal is applied to one stator and said amplified digital PWM complement signal is applied to the other stator.

2. The digital audio amplifier of claim 1, wherein said amplified digital PWM input signal and said amplified digital PWM complement signal each comprise a 1-bit differential signal.

3. The digital audio amplifier of claim 1, wherein said amplification circuit comprises an H-bridge.

4. The digital audio amplifier of claim 3, wherein said H-bridge comprises MOSFETS.

5. The digital audio amplifier of claim 1, wherein said amplified digital PWM input signal and said amplified digital PWM complement signal each has a voltage amplitude of at least about 900 volts.

6. A method of driving an electrostatic loudspeaker having a pair of fixed stators separated by a charged membrane, the digital audio amplifier comprising:
receiving a digital audio signal at a pulse-width-modulation (PWM) generator;
formatting said digital audio signal as a digital PWM input signal;
generating a digital PWM complement signal by calculating the Boolean complement of said PWM input signal at a complement generator;
amplifying said digital PWM input signal and said digital PWM complement signal at an amplification circuit; and
applying said amplified digital PWM signal to the fixed stators of said electrostatic loudspeaker, whereupon said electrostatic loudspeaker generates audible sound waves therefrom.

7. The method of claim 6, further comprising:
low-pass filtering said amplified digital PWM input signal and said digital PWM complement signal by the electrostatic loudspeaker.

8. The method of claim 6, wherein said amplified digital PWM input signal and said amplified digital PWM complement signal each comprise a 1-bit differential signal.

9. The method of claim 6, wherein said amplification circuit comprises an H-bridge.

10. The digital audio amplifier of claim 9, wherein said H-bridge comprises MOSFETS.

11. The digital audio amplifier of claim 6, wherein said amplified digital PWM input signal and said amplified digital PWM complement signal each has a voltage amplitude of at least about 900 volts.
